(19) United States
(12) Patent Application Publication
(10) Pub. No.: US 2007/0096245 A1
(43) Pub. Date: May 3, 2007

(54) Semiconductor device and manufacturing method for the same

(75) Inventor: Masaru Kariyama, Nara (JP)

Correspondence Address: HARNESS, DICKEY & PIERCE, P.L.C., P.O. BOX 8910, RESTON, VA, 20195, US

(73) Assignee: SHARP KABUSHIKI KAISHA, Osaka (JP)

(21) Appl. No.: 10/560,905

(22) PCT Filed: Jun. 19, 2003
(86) PCT No.: PCT/JP03/07765

§ 371 Date: Oct. 23, 2006

(51) Int. Cl. H01L 23/58

(52) U.S. Cl. 257/496

(57) ABSTRACT

The present invention relates to a manufacturing method for a semiconductor device that includes, at least, the step of forming a drift region of a second conductivity type provided with a low concentration region in the semiconductor substrate on, at least, one side in the channel length direction of the gate electrode by means of impurity ion implantations with predetermined implantation angles with four different directions; and the step of forming a high concentration region of the second conductivity type surrounded by the drift region, with the exception of the low concentration region. A semiconductor device having a drift region that can be miniaturized without increase in the number of manufacturing steps as well as a manufacturing method for the same can be provided according to the above described method.

### TECHNICAL FIELD

The present invention relates to a semiconductor device and to a manufacturing method for the same. The present invention relates, in particular, to a semiconductor device having a high withstand voltage which can be utilized, for example, as a power supply IC and to a manufacturing method for the same.

### PRIOR ART

Representative semiconductor devices having high withstand voltages, from among semiconductor devices, are utilized as ICs for power supply, drivers for displays, or the like. FIG. 3 shows a schematic cross sectional view (Prior Art 1) of a semiconductor device having a high withstand voltage. FIG. 3 shows a semiconductor device having a gate electrode 3, a first drift region 6 of a second conductivity type with a low impurity concentration that includes portions located directly beneath the edges of the gate electrode so that the gate electrode overlaps the first drift region, a source region 4 and a drain region 5 of the second conductivity type with a high impurity concentration separated from the gate electrode 3 and surrounded by the first drift region 6. Here, a semiconductor substrate of a first conductivity type is denoted as 1, a gate insulating film is denoted as 2, an edge of the first drift region is denoted as 6A, the border between the drain region and the first drift region is denoted as 6B, an element isolation region is denoted as 8, an interlayer insulating film is denoted as 14, a drain electrode is denoted as 15, a source electrode is denoted as 16 and the length of the first drift region is denoted as 17. The principle of the high withstand voltage in this Prior Art 1 is described below.

A drop in voltage is caused in the drift region 6 when a high voltage is applied to the drain region 5 due to depletion in the first drift region 6 so that the electrical field in the edge 6A of the first drift region beneath the gate electrode 3 is relaxed and, thereby, a high withstand voltage is achieved in Prior Art 1. That is to say, the concentration of the first drift region 6 is made low in order to increase the withstand voltage at the edge 6A of the first drift region and in order to increase the amount of drop in voltage in the first drift region 6.

In addition, the gate electrode 3 overlaps a portion of the first drift region 6, which is beneath the edge of the gate electrode 3, so that the depletion is further increased in this overlapped region due to difference in potential between the first drift region and the gate electrode 3 and so that the electrical field at the edge 6A of the drift region is further relaxed and, thereby, a high withstand voltage is achieved.

FIG. 4(d) shows a schematic cross sectional view of a semiconductor device according to Prior Art 2, which is an improvement of Prior Art 1. This is a semiconductor device having a gate electrode 3, a first drift region 6 of a second conductivity type with a low impurity concentration that includes portions located directly beneath the edges of the gate electrode so that the gate electrode overlaps the first drift region, a second drift region 7 separated from the gate electrode 3 and adjacent to the first drift region 6, a source region 4 and a drain region of the second conductivity type with a high impurity concentration separated from the gate electrode 3 and surrounded by the second drift region 7. The principle of the high withstand voltage in this Prior Art 2 is described below.

It is necessary to make the impurity concentration of the first drift region 6 low so as to increase the amount of drop in voltage in the first drift region 6 in order to increase the withstand voltage at the edge 6A of the first drift region in FIG. 3 of Prior Art 1. On the other hand, a drop in voltage occurs at the border 6B between the drain region and the first drift region due to depletion in first drift region 6 and, therefore, the intensity of the electrical field at the border 6B is increased causing a drop in the withstand voltage.

Therefore, the second drift region 7 is provided surrounding the drain region 5 as shown in FIG. 4(d) wherein the impurity concentration of the second drift region 7 is made higher than that of the first drift region 6 and, thereby, the electrical field at the border 7B between the drain region and the second drift region is relaxed so that a high withstand voltage for the entire transistor is achieved in Prior Art 2. In this figure, 7A indicates the border between the first drift region and the second drift region.

Japanese Unexamined Patent Publication NO.SHO 61 (1986)-180483 corresponds to this Prior Art 2.

The above described technology for enhancement of withstand voltage, however, has problems wherein the number of manufacturing steps is increased and there is a limit in regard to miniaturization of the transistor.

That is to say, it is necessary to use respective photoresist masks 10 to carry out impurity implantations (11, 12) in order to form the drift regions, as shown in FIGS. 4(a) and 4(b), for manufacture of two drift regions having differing impurity concentrations as in Prior Art 2. This increases the number of manufacturing steps.

In addition, at the time of formation of the second drift region, the length 17 of the first drift region undergoes dispersion due to alignment error between the first drift region and the second drift region wherein the impurity has already been introduced producing, in some cases, unstable transistor characteristics. In order to prevent this, it becomes necessary to increase the design value of the length 17 of the first drift region to a value approximately five times as large as the alignment error (the entire length of the drift region is approximately 1 μm in the case wherein the alignment error for manufacture is 0.2 μm) and, therefore, there is a limitation in regard to miniaturization of the transistor.

Furthermore, it is necessary for the width of region of overlap between the gate electrode and the drift region to be approximately two times as long as the alignment error in order to prevent separation of the gate electrode and the drift region due to alignment error of the gate electrode and first drift region 6 at the time of formation of the gate electrode. In the figure, 13 indicates impurity implantation for formation of the source region and the drain region.

### DISCLOSURE OF THE INVENTION

The inventor of the present invention reviewed the above described problems and discovered a semiconductor device that can be manufactured without an increase in the number of steps and that has a drift region which can be miniaturized as well as a manufacturing method for the same according to the present invention.

Thus, the present invention provides a semiconductor device comprising: a semiconductor substrate of a first conductivity type wherein an element isolation region is formed; a gate electrode formed above the semiconductor substrate with a gate insulating film placed therebetween; a sidewall spacer, made of an insulating film, arbitrarily formed on the sidewall of the gate electrode; a drift region of a second conductivity type provided with a low concentration region formed in the semiconductor substrate under, at least, one edge side in the channel length direction of the gate electrode; a high concentration region of the second conductivity type surrounded by the drift region, with the exception of the low concentration region; an interlayer insulating film formed over the entire surface of the semiconductor substrate; and a contact hole as well as a metal wire formed in a predetermined portion,

wherein the drift region of the second conductivity type provided with the low concentration region is a region formed by means of impurity ion implantation with predetermined implantation angles respect to a surface of the semiconductor substrate and with four different directions.

Furthermore, the present invention provides a manufacturing method for a semiconductor device comprising the step of:

forming a gate electrode via a gate insulating film above a semiconductor substrate of a first conductivity type, wherein an element isolation region is formed;

arbitrarily forming sidewall spacers, made of an insulating film, on the sidewalls of the gate electrode;

forming a drift region of a second conductivity type provided with a low concentration region in the semiconductor substrate under, at least, one edge side in the channel length direction of the gate electrode by means of impurity ion implantations with predetermined implantation angles respect to a surface of the semiconductor substrate and with four different directions;

forming a resist pattern and forming a high concentration region of the second conductivity type surrounded by the drift region, with the exception of the low concentration region, using the resist pattern;

removing the resist pattern and forming an interlayer insulating film over the entire surface of the semiconductor substrate; and

forming a contact hole in predetermined portion and forming a metal wire.

In addition, the present invention provides a manufacturing method for a semiconductor device comprising the step of:

forming a gate electrode via a gate insulating film above a semiconductor substrate of a first conductivity type, wherein an element isolation region is formed;

arbitrarily forming sidewall spacers, made of an insulating film, on the sidewalls of the gate electrode;

forming a trench by etching the semiconductor substrate using a mask constituted the gate electrode and the sidewall spacer arbitrarily formed

forming a drift region of a second conductivity type provided with a low concentration region in the semiconductor substrate under, at least, one edge side in the channel length direction of the gate electrode by means of impurity ion implantation with predetermined implantation angles respect to a surface of the semiconductor substrate and with four different directions;

forming a resist pattern and forming a high concentration region of the second conductivity type surrounded by the drift region, with the exception of the low concentration region, using the resist pattern;

removing the resist pattern and forming an interlayer insulating film over the entire surface of the semiconductor substrate; and

forming a contact hole in predetermined portion and forming a metal wire.

### BRIEF DESCRIPTION OF THE DRAWINGS

FIG. 1(a) to 1(c) are schematic cross sectional views showing the steps of manufacture of the semiconductor device in Embodiment 1.

FIG. 3(a) to 3(c) are schematic cross sectional views showing the steps of manufacture of the semiconductor device in Embodiment 3.

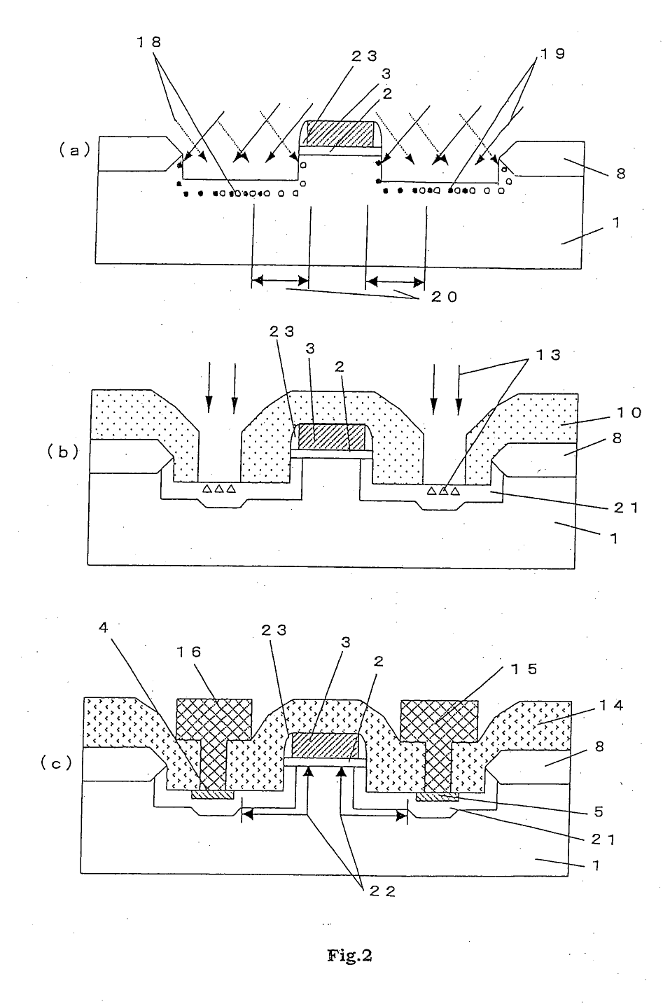

FIG. 3 is a schematic cross sectional view of a semiconductor device of Prior Art 1.

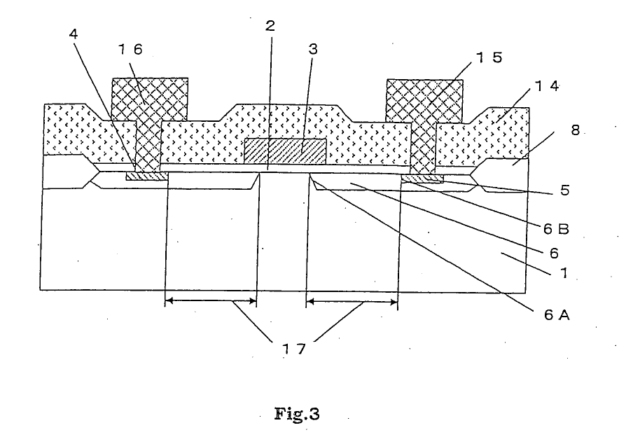

FIG. 4(a) to 4(d) are schematic cross sectional views showing the steps of manufacture of the semiconductor device in Prior Art 2.

### MODE FOR CARRYING OUT THE INVENTION

The present invention is characterized in that the angle of impurity implantation for formation of the drift region, which is conventionally carried out at an incident angle of 0° vis-à-vis the surface of the wafer, is tilted (to 30°, or more, for example) and, furthermore, the direction of ion implantation is changed so that (1) ion implantation is limited in the region adjacent to the portions directly beneath the edge of the gate electrode due to the shadow created by the gate electrode and, thereby, this region has a low impurity concentration and so that (2) a drift region is formed through the implantation of impurities directly beneath the edge of the gate electrode due to diagonal implantation such that the gate electrode overlaps a portion of the drift region, which is beneath the edge of the gate electrode.

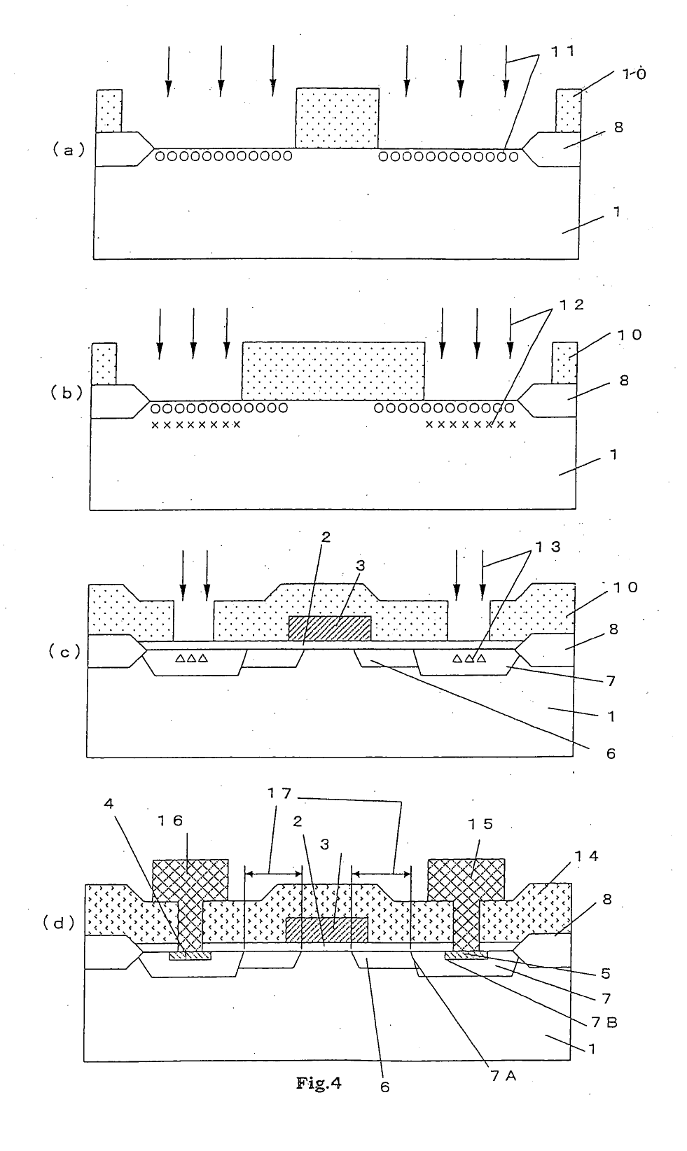

Thus, the step of forming the first drift region according to Prior Art 2 becomes unnecessary. In addition, the width of the region of overlap between the gate electrode and the drift region as well as the length of the low concentration region are determined by the incident angle of impurity implantation and by the thickness of the gate electrode and, therefore, these values are stable and it is possible to miniaturize the semiconductor device. Concretely, the semiconductor device can be approximately 10% to 40% more greatly miniaturized than the semiconductor device in FIG. 4(d) of Prior Art 2.

In addition, the sidewall spacer made of an insulating film is selectively formed on the sidewalls of the gate electrode and, thereby, the depth of implantation directly beneath the edge of the gate electrode due to diagonal implantation can be limited in the subsequent step of impurity implantation for the formation of the drift region. Therefore, the width of the region of overlap between the gate electrode and the drift region can be reduced, and the semiconductor device can be miniaturized.

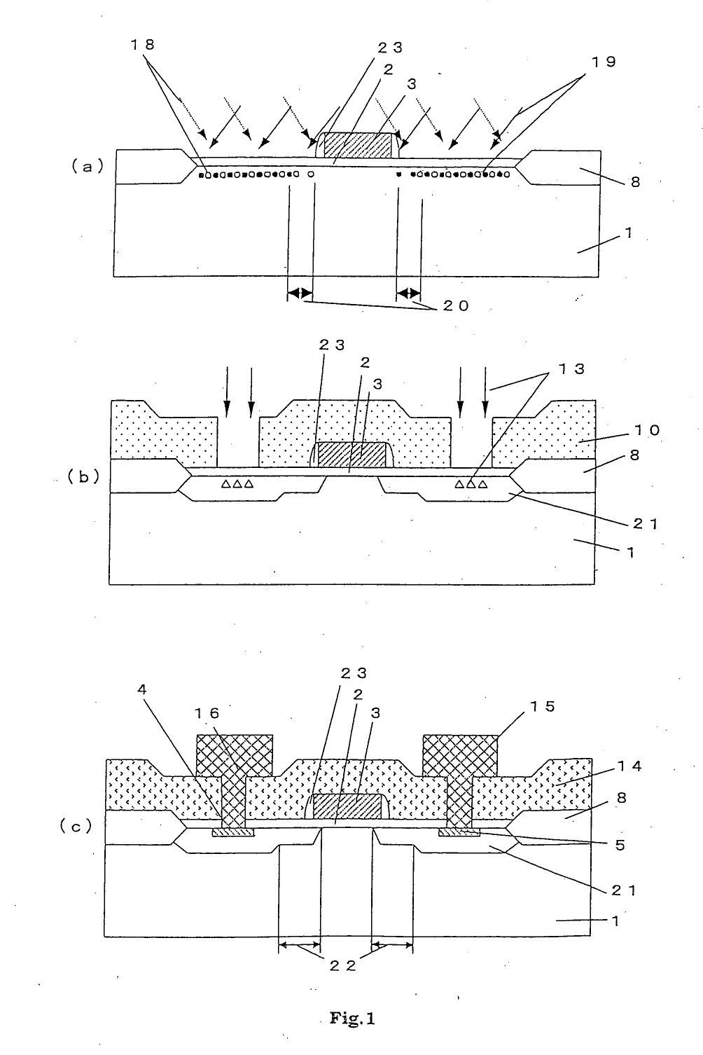

In addition, the drift region is formed in a trench form, as the surface of the semiconductor substrate, of which the top is level with the surface of the semiconductor substrate directly beneath the gate electrode and, thereby, the impurity concentration becomes the lowest in the sidewalls of the trench adjacent to the portions directly beneath the edges of the gate electrode and the impurity concentration becomes the second lowest in a portion of the drift region at the bottom of the trench. Therefore, the effective length of the low concentration region can be expanded so that the semiconductor device can achieve a high withstand voltage. Concretely, the withstand voltage of the semiconductor device can be enhanced 1.1 to 1.3 times higher than the semiconductor device of FIG. 1(c).

Here, in the case wherein the voltage applied to the source region is low, the drift region on the source region side can be omitted so that a source region with a high impurity concentration is provided adjacent to the portion directly beneath the edge of the gate electrode and, thereby, miniaturization can be achieved.

The semiconductor substrate utilized in the present invention is not particularly limited and known substrates, such as silicon substrates, silicon germanium substrates, and the like, may be utilized.

An element isolation region is formed in the semiconductor substrate. The element isolation region may be either a LOCOS isolation region or a trench isolation region.

The gate electrode is formed in a predetermined portion above the semiconductor substrate in a region divided by the element isolation region with the gate insulating film intervened between the gate electrode and the semiconductor substrate. A silicon oxide film, a silicon nitride film, a film made up of layers of these films, and the like, can be cited as the gate insulating film. A metal film, such as of Al or of Cu, a polysilicon film, a silicide film of silicon and a high melt point metal (for example, titanium, tungsten, or the like), a film (polycide film) made up of layers of a polysilicon film and a silicide film, for example, can be cited as the gate electrode. The gate insulating film can be formed according to a thermal oxidation method, a sputtering method, or the like, that is selected in accordance with the material, and the gate electrode can be formed according to a CVD method, a vapor deposition method, or the like, that is selected in accordance with the material.

A sidewall spacer made of an insulating film (for example, silicon oxide film or silicon nitride film) may be formed on the sidewall of the gate electrode. The sidewall spacer can be formed according to a CVD method, a sputtering method, or the like, that is selected in accordance with the material.

Furthermore, a trench may be created in the semiconductor substrate by means of dry or wet etching using a mask constituted the gate electrode and the sidewall spacer arbitrarily formed. The depth of the trench may be, for example, 0.1 μm to 0.5 μm. The form of the trench is not particularly limited and a form wherein the walls of the trench are vertical, a form wherein the bottom of the trench is smaller than the opening of the trench, a form wherein the bottom of the trench is larger than the opening of the trench, or the like, can be cited.

The drift region of the second conductivity type provided with a low concentration region at an end in the channel length direction of the gate electrode is formed on, at least, the side where the drain region is formed in the semiconductor substrate, by means of impurity ion implantations with predetermined implantation angles and with four different directions. The implantation angles differ depending on the desired characteristics of the semiconductor device and, for example, implantation can be carried out at an angle of 30°, or greater, and, more concretely, the angle can be selected to be in a range of from 30° to 70°.

Here, the four different directions may be in any relationship to each other as long as the above described drift region can be formed. In particular, it is preferable for the four directions to be directions wherein a first direction is a direction parallel to the channel width direction and wherein the other three directions have incident angles of 90°, 180° and 270°, respectively, relative to the above described first direction.

Furthermore, the drain region of the second conductivity type with a high concentration surrounded by the drift region, with the exception of the low concentration region, is formed using a resist pattern. Here, the source region may be formed within the drift region. In addition, the source region may be solely formed so as to overlap the portion directly beneath a sidewall of the gate electrode.

In addition, an interlayer insulating film is provided over the entire surface of the semiconductor substrate and a contact hole as well as a metal wire are provided in predetermined portions. The interlayer insulating film is not particularly limited and any known films, such as a silicon oxide film, a SOG film, or the like, formed according to known methods can be utilized. In addition, the predetermined portion wherein the contact hole is formed can be cited a portion above the source region, above the drain region, above the gate electrode, and the like. An Al film, a Cu film, and the like, can be cited for the metal wire.

### EMBODIMENTS

The semiconductor devices and manufacturing methods for the same according to the embodiments of the present invention are concretely described below with reference to values.

### Embodiment 1

FIG. 1(c) shows a schematic cross sectional view of the semiconductor device according to Embodiment 1.

A semiconductor substrate 1 of a first conductivity type is, for example, of the P type and has a boron concentration of approximately 1×10¹⁵/cm³. An element isolation region 8 having a thickness of approximately 400 nm is located in this substrate. In addition, a gate insulating film 2 having a thickness of, for example, 40 nm and a gate electrode 3 made of polycide having a thickness of, for example, 200 nm are formed. The channel length of this gate electrode 3 is approximately 1 μm and sidewall spacers 23 made of an insulating film are selectively formed on the sidewalls of the gate electrode, wherein the film thickness of the bottom portions of the spacers is, for example, 100 nm.

In addition, a drift region 21 is formed in a self-aligning manner so as to include the portion directly beneath an edge of the gate electrode 3 so that the gate electrode overlaps the drift region by approximately 0.1 μm. The length 22 of the low concentration region of this drift region is approximately 0.2 μm wherein the low concentration region is of a concentration of 0.9×10¹⁷/cm³ and wherein the depth of the junction thereof is approximately 0.4 μm. In addition, the concentration of the drift region itself is 1.2×10¹⁷/cm³ and the depth of the junction thereof is approximately 0.5 μm.

The distance between the gate electrode 3 and the drain region 5 is 1 μm.

The manufacturing method for the semiconductor device in FIG. 1(c) is described in reference to schematic cross sectional views showing the steps of manufacture of the semiconductor device in FIGS. 1(a) to 1(c).

In reference to FIG. 1(a), the element isolation region 8 is selectively formed in the semiconductor substrate 1 and, then, the gate insulating film 2 is formed and, moreover, the gate electrode 3 is formed.

Sidewall spacers 23 made of an insulating film are selectively formed on the sidewalls of the gate electrode 3. The film thickness at the bottoms of sidewall spacers 23 is adjusted according to the width of the region of overlap between the gate electrode and the subsequently formed drift region 21.

Impurity implantation for the formation of the drift region is carried out on the surface of the semiconductor substrate as described above so that ion implantation (example phosphorus) is carried out from four different directions having an energy of approximately 180 keV and an implantation angle of 45° wherein the total amount of phosphorus ion becomes approximately 7×10¹²/cm². Two directions out of the four directions of ion implantation are parallel to the channel width direction wherein these two directions are 180° opposite to each other while the other two directions are parallel to the channel length direction wherein these two directions are 180° opposite to each other in embodiment 1. In addition, it is possible to appropriately select the implantation angle to be in a range of from 30° to 70° in order to adjust the width of overlap of the drift region 21. At this time the amount of energy, the implantation amount and the angle of implantation are adjusted so as to gain the desired withstand voltage by determining the subsequently gained length 22 of the low concentration region.

At this time, in reference to FIG. 1(a), shadow 20 of the gate electrode is formed in the region adjacent to gate electrode 3 due to a diagonal impurity implantation 19 for the formation of the drift region, which is in the opposite direction to a diagonal impurity implantation 18 for the formation of the drift region and, thereby, the amount of impurity implanted in this region is limited.

In the case of this embodiment the same amount of impurities are implanted in all four directions and, therefore, the amount of impurity implanted in the region adjacent to the gate electrode 3 becomes approximately ¾ of the entire implantation amount because shadow 20 of the gate electrode is formed in only one direction of ion implantation, and this drift region is formed starting from an edge of the gate electrode 3 so as to have a width of approximately 200 nm.

After that, in reference to FIG. 1(b), annealing is carried out at 800° C. for approximately 10 minutes in an N₂ atmosphere so as to activate the drift region.

Next, arsenic implantation 13, for example, is selectively carried out with an energy of 40 keV for the formation of the drain and source regions with an amount of implantation of 3×10¹⁵/cm² using a photosensitive resist mask 10.

Next, in reference to FIG. 1(c), the interlayer insulating film 14 is formed so as to have, for example, a thickness of 900 nm and contact holes are formed wherein electrodes are formed.

After that, a transistor having a high withstand voltage can be manufactured according to a known method.

### Embodiment 2

This Embodiment 2 is the same as the above described Embodiment 1 except for that no sidewall spacers are formed. Greater miniaturization of the semiconductor device can be achieved because the spacers are not formed.

### Embodiment 3

FIG. 2(c) shows a schematic cross sectional view of a semiconductor device according to Embodiment 3.

A semiconductor substrate 1 of the first conductivity type is, for example, of the P type and has a boron concentration of approximately 1×10¹⁵/cm³. An element isolation region 8 having a thickness of approximately 400 nm is located in this substrate and, then, a gate insulating film 2 having a thickness of, for example, 40 nm and a gate electrode 3 made of polycide having a thickness of, for example, 200 nm are formed. The channel length of this gate electrode 3 is approximately 1 μm and sidewall spacers 23 made of an insulating film are selectively formed on the sidewalls of the gate electrode, wherein the film thickness of the bottom portions of the spacers is, for example, 100 nm.

In addition, a drift region 21 is formed in a self-aligning manner so as to include the portion directly beneath an edge of the gate electrode 3 so that the gate electrode overlaps the drift region by approximately 0.1 μm. This drift region 21 is formed in the sidewalls and bottom of a trench having a depth of 0.2 μm. Length 22 of the low concentration region of this drift region is approximately 0.6 μm as the sum of the sidewall portion and the bottom portion wherein the concentration of the sidewall portion is 0.3×10¹⁷/cm³, the depth of the junction thereof is approximately 0.2 μm and wherein the concentration of the bottom portion is 0.9×10¹⁷/cm³ and the depth of the junction thereof is approximately 0.4 μm. In addition, the concentration of the drift region itself is 1.2×10¹⁷/cm³ and the depth of the junction thereof is approximately 0.5 μm.

The manufacturing method for the semiconductor device in FIG. 2(c) is described in reference to schematic cross sectional views showing the manufacturing steps of the semiconductor device of FIGS. 2(a) to 2(c).

In reference to FIG. 2(a), the element isolation region is selectively formed in the semiconductor substrate 1 of the first conductivity type and, then, the gate insulating film 2 is formed and, moreover, the gate electrode 3 is formed.

Sidewall spacers 23 made of an insulating film are selectively formed on the sidewalls of the above described gate electrode. The film thickness of the spacers is adjusted according to the width of the region of overlap between the gate electrode and the subsequently formed drift region 21. In addition, the surface of the semiconductor substrate is processed so as to be in the trench form, wherein the drift region is subsequently formed, with a depth of, for example, 0.2 μm after the formation of sidewall spacers.

Impurity implantation for the formation of the drift region is carried out on the surface of the semiconductor substrate as described above so that ion implantation (example phosphorus) is carried out from four different directions having an energy of approximately 180 keV and an implantation angle of 45° wherein the total amount of phosphorus ion becomes approximately 7×10¹²/cm². Two directions out of the four directions of ion implantation are parallel to the channel width direction wherein these two directions are 180° opposite to each other while the other two directions are parallel to the channel length direction wherein these two directions are 180° opposite to each other. At this time the amount of energy, the implantation amount and the angle of implantation are adjusted so as to gain the desired withstand voltage by determining the subsequently gained length 22 of the low concentration region.

At this time, in reference to FIG. 2(a), shadow 20 of the gate electrode is formed in the region adjacent to gate electrode 3 due to a diagonal impurity implantation 19 for the formation of the drift region, which is in the opposite direction to a diagonal impurity implantation 18 for the formation of the drift region and, thereby, the amount of impurity implanted in this region is limited.

In the case of this embodiment the same amount of impurities are implanted in all four directions and, therefore, the amount of impurity implanted in the sidewall region of the trench adjacent to the gate becomes ¼ of the entire implantation amount because ion implantation is carried out in only one direction and the amount of impurity ions implanted in the low concentration region at the bottom of the trench becomes ¾ of the entire ion implantation amount due to the shadow formed in only one direction.

In the case of a diagonal 45° implantation, shadow 20 of the gate electrode has a length of 400 nm, which is the sum of the height of the gate electrode and the depth of the trench that is etched in the silicon while the drift layer has a length of approximately 600 nm. In addition, it is possible to appropriately select the implantation angle to be in a range of from 30° to 70° in order to adjust the length of the drift region 21.

After that, in reference to FIG. 2(b), annealing is carried out at 800° C. for approximately 10 minutes in an N₂ atmosphere so as to activate the drift region.

Next, arsenic implantation 13, for example, is selectively carried out with an energy of 40 keV for the formation of the drain and source regions with an amount of implantation of 3×10¹⁵/cm² using a photosensitive resist mask 10.

Next, in reference to FIG. 2(c), the interlayer insulating film 14 is formed so as to have, for example, a thickness of 900 nm and contact holes are formed wherein electrodes are formed so as to form a transistor having a high withstand voltage.

### Embodiment 4

Though a semiconductor device having a structure wherein a high voltage can be applied to the source region is gained according to any of the above described Embodiments 1 to 3, the drift region can be omitted on the source region side so that source region 4 having a high concentration can be provided adjacent to the portion directly beneath an edge of gate electrode 3 in the case wherein a low voltage is applied to the source region.

The step of forming the first drift region becomes unnecessary so that the length of a region of overlap between the gate electrode and the drift region as well as the length of the low concentration region are determined by the incident angle of impurity implantation and by the thickness of the gate electrode and, therefore, it becomes possible to stabilize the characteristics of the semiconductor device and to achieve miniaturization of the semiconductor device according to the present invention.

1. A semiconductor device comprising: a semiconductor substrate of a first conductivity type wherein an element isolation region is formed; a gate electrode formed above the semiconductor substrate with a gate insulating film placed therebetween; a sidewall spacer, made of an insulating film, arbitrarily formed on the sidewall of the gate electrode; a drift region of a second conductivity type provided with a low concentration region formed in the semiconductor substrate under, at least, one edge side in the channel length direction of the gate electrode; a high concentration region of the second conductivity type surrounded by the drift region, with the exception of the low concentration region; an interlayer insulating film formed over the entire surface of the semiconductor substrate; and a contact hole as well as a metal wire formed in a predetermined portion,
wherein the drift region of the second conductivity type provided with the low concentration region is a region formed by means of impurity ion implantation with predetermined implantation angles respect to a surface of the semiconductor substrate and with four different directions.

2. A semiconductor device of claim 1, wherein the semiconductor substrate has a trench formed by means of etching using a mask constituted the gate electrode and the sidewall spacer arbitrarily formed, and the drift region and the high concentration region are formed in the trench.

3. A semiconductor device of claim 1, wherein the drift region of the second conductivity type provided with a low concentration region is formed on both ends in the channel length direction of the gate electrode, and the high concentration regions of the second conductivity type are formed as a source region and a drain region in the drift region with the exception of the low concentration region.

4. A semiconductor device of claim 2, wherein the implantation angle is from 30° to 70°.

5. A semiconductor device of claim 1, wherein the four different directions are directions wherein a first direction is a direction parallel to the channel width direction and the other three directions have incident angles of 90°, 180° and 270°, respectively, relative to the first direction.

6. A manufacturing method for a semiconductor device comprising the step of:
forming a gate electrode via a gate insulating film above a semiconductor substrate of a first conductivity type, wherein an element isolation region is formed;
arbitrarily forming sidewall spacers, made of a insulating film, on the sidewalls of the gate electrode;
forming a drift region of a second conductivity provided with a low concentration region in the semiconductor substrate under, at least, one edge side in the channel length direction of the gate electrode by means of impurity ion implantations with predetermined implantation angles respect to a surface of the semiconductor substrate and with four different directions;
forming a resist pattern and forming a high concentration region of the second conductivity type surrounded by the drift region, with the exception of the low concentration region, using the resist pattern;
removing the resist pattern and forming an interlayer insulating film over the entire surface of the semiconductor substrate; and
forming a contact hole in predetermined portion and forming a metal wire.

7. A manufacturing method for a semiconductor device comprising the step of:
forming a gate electrode via a gate insulating film above a semiconductor substrate of a first conductivity type, wherein an element isolation region is formed;
arbitrarily forming sidewall spacers, made of an insulating film, on the sidewalls of the gate electrode;
forming a trench by etching the semiconductor substrate using a mask constituted the gate electrode and the sidewall spacer arbitrarily formed
forming a drift region of a second conductivity type provided with a low concentration region in the semiconductor substrate under, at least, one edge side in the channel length direction of the gate electrode by means of impurity ion implantation with predetermined implantation angles respect to a surface of the semiconductor substrate and with four different directions;
forming a resist pattern and forming a high concentration region of the second conductivity type surrounded by the drift region, with the exception of the low concentration region, using the resist pattern;
removing the resist pattern and forming an interlayer insulating film over the entire surface of the semiconductor substrate; and
forming a contact hole in predetermined portion and forming a metal wire.

8. A manufacturing method for a semiconductor device of claim 6, wherein the implantation angle is from 30° to 70°.

9. A manufacturing method for a semiconductor device of claim 6, wherein the drift region of the second conductivity type provided with a low concentration region is formed on both ends in the channel length direction of the gate electrode, and the high concentration regions of the second conductivity type are formed as a source region and a drain region in the drift region with the exception of the low concentration region.

10. A manufacturing method for a semiconductor device of claim 6, wherein the four different directions are directions wherein a first direction is a direction parallel to the channel width direction and the other three directions have incident angles of 90°, 180° and 270°, respectively, relative to the first direction.

11. A manufacturing method for a semiconductor device of claim 7, wherein the implantation angle is from 30° to 70°.

12. A manufacturing method for a semiconductor device of claim 7, wherein the drift region of the second conductivity type provided with a low concentration region is formed on both ends in the channel length direction of the gate electrode, and the high concentration regions of the second conductivity type are formed as a source region and a drain region in the drift region with the exception of the low concentration region.

13. A manufacturing method for a semiconductor device of claim 7, wherein the four different directions are directions wherein a first direction is a direction parallel to the channel width direction and the other three directions have incident angles of 90°, 180° and 270°, respectively, relative to the first direction.
